(19) United States
(12) Patent Application Publication
(10) Pub. No.: US 2011/0080931 A1
(43) Pub. Date: Apr. 7, 2011

(54) CIRCULAR SEMICONDUCTOR LASERS HAVING LATTICES FOR VERTICAL EMISSION

(75) Inventors: Alessandro TREDICUCCI, Pisa (IT); Fabio BELTRAM, Gorizia (IT); Lucas MAHLER, Pisa (IT)

(73) Assignee: SCUOLA NORMALE SUPERIORE, Pisa (IT)

(21) Appl. No.: 12/940,209

(22) Filed: Nov. 5, 2010

Related U.S. Application Data
(63) Continuation-in-part of application No. PCT/IB2009/005413, filed on Apr. 28, 2009.

(30) Foreign Application Priority Data
May 5, 2008 (IT) PI2008A000038

(51) Int. Cl. H01S 5/34; H01S 5/10; H01S 3/06; B82Y 20/00; B82Y 99/00

(52) U.S. Cl. 372/45.012; 372/45.01; 372/67; 977/755; 977/951

(57) ABSTRACT

A semiconductor laser includes a laser resonator (1) having a planar active region (3), a first (2) and a second (6) wave-guide layer that define the active region (3). The resonator (1) has a shape that is defined by a perimeter, along which the first layer (2) radiation guide has a plurality of cuts (4) forming a lattice. The cuts are made as at least two adjacent slits (4a, 4b) and a zone between the slits in which an uncut portion (5a) of wave-guiding layer is present. In the case of a circular semiconductor laser, the number of cuts (4) is a prime number, or an odd number that is a multiple of a prime number, the prime number being greater than or equal to five. This way, it is avoided that resonance modes evolve outside of the zone with the cuts, or in any case with a component that is different from zero of the wave vector in a radial direction, and a pure whispering gallery operating mode is obtained, with maximum of the emitted radiation that evolves in a vertical direction, i.e. orthogonal to the plane of the laser resonator, and without the laser emitting radiation evolving in a radial direction.

This application is a continuation-in-part of PCT/IB2009/005413 filed Apr. 28, 2009, which is incorporated herein by reference.

### BACKGROUND OF THE INVENTION

1. Field of the Invention

The present invention relates to laser devices; more precisely, it relates to laser devices which use a laser resonator that has a planar geometry in order to be adapted for a laser vertical emission, i.e. orthogonal to the plane of the same laser resonator.

In particular, but not exclusively, the invention is adapted to be associated to Quantum-Cascade Laser type emitters, which normally have working frequencies in the range of Terahertz (THz QCL).

2. Description of Related Art

In addition to traditional Fabry-Perot (FP) laser devices, which utilise two parallel reflectors that force the radiations to be emitted according to a longitudinal direction, and are associated with waveguides to limit otherwise directed radiations, laser devices are known which use a different emission geometry; among the latter, there are laser devices that utilise circular geometry resonators.

With respect to a traditional FP laser device, in a circular laser resonator the terminal mirrors of the resonator are missing, and the radiations are blocked along a circular path. More precisely, by using as a waveguide a high refraction index material, the obtained photons that are close to the circumference are reflected at a predetermined angle that allows a total reflection, such that the photons remain within the resonator. The modes that resulting from this structure are called “whispering gallery”, due to the analogy with the well-known acoustic phenomenon that takes place under particular architectural vaults. Thanks to this structure, dispersions are reduced to a minimum value, and depend mainly on diffusion phenomena, which are caused for example by circumference imperfections.

However, the practical utility of circular geometry resonators is compromised by a low power output that, in addition, is spread along the laser resonator plane.

Concerning a possible integration with terahertz laser devices (THz QCLs), with the existing laser systems the waveguides operate according to propagation modes whose transversal sections are quite smaller than the wavelength that the emitted radiation would have if such radiation were emitted in open space. Since this radiation is emitted through the cut edge of a waveguide, a strongly diverging output beam of radiations can be obtained, which is therefore of scarce practical use.

On the other hand, the use of vertically emitting recesses (Vertical Cavity Surface Emitting Laser—VCSEL) is known, which makes it possible to obtain radiation beam profiles that are very useful both in the visible range and in the near infrared range. However, the VCSEL cannot be used with devices that are based on the quantum-cascade principle, owing to the rules of selection of the electronic transitions that prevent the emission of radiations in vertical direction.

A circular geometry resonator is known which has a disc or ring like shape, and uses a waveguide structure that furthermore acts like a vertical barrier, i.e., a barrier which is perpendicular to the radiation guide plane. Nevertheless, a disc resonator is described in EP1544967A1, which can be used also for laser emission, and which has a lattice that allows vertically bundling the outlet radiations. The disc can resonate in a whispering gallery mode if a substantially circular recess is created. The lattice can be used in order to select the azimuth mode, i.e. the circumferential mode, for the laser action, according to the mechanisms of distributed feedback (DFB) lasers. In particular, the lattice is made on the disc plane and, for example, it can be structured on the boundary of the disc plane by means of radial cuts.

However, a resonator as described in EP1544967A1 cannot ensure an actual whispering gallery operation mode, and cannot assure that the maximum of the emission is performed in vertical direction.

In fact, the advantages of such a resonator are that vertically emitting planar laser devices can be made. In particular, only if the lattice is a second order one, i.e. only if the lattice pitch corresponds to the radiation wave length, or if a higher order lattice pitch that is multiple of the second order, i.e. if the lattice pitch is a multiple of the radiation wave length, the maximum radiation intensity is obtained in a vertical direction.

However, in a circular symmetry laser device, once the wavelength has been fixed, the most preferred laser emitting mode may also provide a vector of propagation which has a radial component, such that the lattice, even if it has a pitch that corresponds to the radiation length, behaves actually as a first order lattice, and the maximum of the radiation intensity that is emitted by the laser resonator is remarkably diverging, and is of scarce practical use.

In EP0533390, JP06152047, JP5090669 a resonator is disclosed for obtaining circular laser device having perimetral grooves. The number of the grooves is a prime number or an odd number multiple of a prime number respectively 5, 25 and 65.

In devices of this type the problem arises that in order to increase the radiation extraction efficiency the ratio between the surface of the grooves and the surface of uncut zones should be as large as possible, for example 50%. Such large grooves, however, particularly with long wavelength devices, such as THz QC laser devices, reduce the current injection along the perimeter.

Further resonators are known of linear type, such as ridges, buried heterostructure waveguides, etc., in which laser radiation is also extracted in the vertical direction by means of second-order periodic grating which also provides the feedback, so called second-order distributed feedback lasers.

Such linear second-order DFB resonators have certain drawback, particularly when they are applied to THz QCLs operating in metallic waveguides. In particular, such grating resonators provide two lasing modes, i.e. symmetric and anti-symmetric with respect to the grating. However, only one, i.e. typically the symmetric one, is able to efficiently radiate in the vertical direction, due to an interference effect. The other, typically the asymmetric one, produces a much lower intensity and a dual-lobe beam profile and is, therefore, much less appealing for industrial applications. The latter mode, however, since it presents lower losses, is then most often the only one capable of reaching the lasing condition.

### SUMMARY OF THE INVENTION

It is a feature of the present invention to provide a laser resonator that allows a laser emission in the terahertz frequency range, and, in particular, a laser resonator that has a quantum-cascade active region.

It is also a feature of the present invention to provide a laser resonator that allows a whispering gallery type operation mode in which the maximum radiation is obtained in a vertical direction.

It is also a feature of the present invention to provide a laser resonator that allows emitting a regular profile, low divergence and high efficiency radiation.

It is a further feature of the present invention to provide a resonator that makes it possible to control the efficiency of the vertical emission from the grating mode radiating vertically, its optical losses, as well as the amount of feedback.

It is a further feature of the present invention to provide a resonator that makes it possible to maximise the output power in the vertical direction, at the same time ensuring that only the symmetric mode reaches the laser threshold, producing regular, single-lobe beam profiles.

These and other objects are achieved by a planar resonator which is adapted to be associated to a laser, said resonator comprising an planar active region, a first and a second wave-guiding layer that contains said active region; wherein said resonator has a shape that is defined by a perimeter, along said perimeter said first wave-guiding layer having a plurality of cuts that form a lattice, wherein said cuts are made by at least two adjacent slits and a central zone between the slits in which metal is present.

This way, a cut is defined by a central zone in which metal is present between two slits, or two zones in which metal is present between three slits, etc., achieving the same extraction efficiency of a cut in which the metal is totally removed. This way, the electric pumping efficiency of the cut zone is increased, which is particularly useful in the case of very high wavelengths.

In a preferred embodiment, the perimeter can be circular, and the cuts are radial cuts, wherein the number of said cuts can be a prime number or an odd number that is a multiple of a prime number, said prime number greater than or equal to five.

This way, the formation of resonance modes that extend out of the cut zone or which have a wave vector with a zero component in the radial direction is avoided. Therefore, a real whispering gallery type operating mode is obtained, in which the maximum of the radiation takes place in a vertical direction, i.e. orthogonally to the plane of the laser resonator.

In particular, when the number of radial cuts is a prime number, the laser action surprisingly does not evolve according to one of the resonator modes by the which lattice behaves as if it were an even order lattice; instead, the lattice behaves as if it were a second or higher order lattice.

More precisely, let λ be the wavelength of the radiations as emitted by the laser, Λ be the lattice pitch, i.e., the distance between two cuts, and K=2π/λ, be the wave vector of the radiations, the lattice behaves as a second order lattice, if the component of K in the circumferential direction of the lattice is 2π/Λ, whereas the lattice behaves as a first order lattice if the component of K in the circumferential direction of the lattice is π/Λ. This is possible, even if a same λ value is kept, which has a radial component that is different from zero. This radial component causes, however, a preferential emission direction that is no longer vertical.

Instead, if the number of the cuts along the laser resonator boundary is a prime number, the lattice does not allow the circumferential component to be π/Λ; therefore the lattice behaves like a second order lattice and ensures a vertical laser emission.

A similar situation occurs for frequencies set in the range of terahertz, in the presence of a number of cuts that is not a prime number, but is an odd number that is a multiple of a prime number, where the prime number is greater than or equal to five. In this case, in fact, since the resonator is circular, even if it is theoretically possible that the resonator “lasers” in zones other than the lattice, i.e., towards the centre of the disc, at a distance that is a multiple of the wavelength, such areas cannot “laser” due to the small diameter of the disc.

Therefore, if a laser disc is integrated to a lattice in such a way that the lattice is directly manufactured on the laser disc circular boundary, and that the number of the cuts is chosen according to the above, two important results are obtained:
firstly, the laser is forced to work in a whispering gallery mode; this allows minimum radiation dispersion, thanks to the total inner reflection along the circumference; and makes it possible to couple this oscillation mode with the vertical direction, enabling therefore a high directional power emission,
secondly, the arrangement of the lattice along the circumference disk allows most closely an approximation to an infinite lattice, which enables to control at best the resonator modes; on the contrary, in the case of linear DFB resonator, which are used in compact semiconductor laser devices, the phase relationship between the facets and the lattice is difficult to control, which lowers the single mode devices efficiency.

The lattice can be made by means of photolithography and etching techniques at any vertical position of the radiation guide, in the active region, above or below the active region, or within the coating. In alternative, it can be obtained by laying a plurality of layers on the radiation guide, such layers having the shape of a lattice. In case of a ring laser, or of a disc laser, the lattice can be made both on the circumference, and along the radius of the disc.

A particular embodiment of the invention is a terahertz quantum-cascade laser (THz QCL). This is obtained by interposing a semiconductor active region between two metal waveguides, and by associating it to a lattice that has been formed by radial cuts at the boundary of the disc.

This advantageous wave guide embodiment, which comprises a double metal layer and a lattice, is explained below. An important feature of the manufacture of such laser devices is the use of surface plasmons (SP) to make the resonator, i.e. the use of electromagnetic signals that exist at the interface between two materials that have two different dielectric constants values, one of which is positive, as in case of a semiconductor, and the other is negative, the other material being normally a metal. These optical ways travel along the interface between the two materials and decay exponentially and perpendicularly to the interface. Their intrinsic transversal-magnetic TM polarization obeys to the selection rules of “intersubband” transitions. Furthermore, since the mode achieves peak values at the interface, it can be easily changed to create a patterning on the metal layer, i.e., on the lattice, which therefore would change the spectral features of the resonator.

Consequently, by introducing a periodic corrugation on an SP wave guide a quantum-cascade laser is obtained with a distributed feedback (DFB) in the terahertz range frequencies with steady emissions in a single mode. This conditioning step of the resonator mode, along with a typical wavelength that is two orders of magnitude higher than the wavelength of the optical laser, makes the quantum-cascade laser adapted to develop new concepts of resonators. Furthermore, the wavelength of the radiations in the field of THz and the strong influence of the perimeter of the resonator, which is typical of the wave guide metal, allows an easy production of the lattice. Then, owing to the invention, it is possible to obtain a semiconductor quantum-cascade laser in the field of THz obtaining for these frequencies a vertical laser emission.

Advantageously, said laser resonator has a semiconductor active region that is arranged between two doped semiconductor layers, apart from a central zone, where the doped layer is missing. This way, any emission is prevented from leaving the central zone of the laser resonator, thus forcing further the device to emit radiations in a whispering gallery mode, only in the lattice region. This is particularly useful if the coupling coefficient of the lattice, indicated as κ, is particularly small, in particular κ<1/L, where L is the length of the circumference.

Advantageously, said laser resonator has said first and second wave-guiding layers that are made of a metal, preferably a metal selected from the group comprised of: gold, chromium palladium titanium germanium, or combinations thereof, for example chromium/gold, palladium/germanium, titanium/gold alloys, etc.

Advantageously, the lattice filling coefficient, i.e. the ratio between the surface of the cuts and the surface of uncut zones, is set between 40% and 60%, for example it is set at 50%.

Advantageously, said number of cuts is a prime number that is selected from the group comprised of: five, seven, eleven, thirteen, seventeen, nineteen, twenty-three, twenty-nine, thirty-one, thirty-seven, forty-one, forty-three, and forty-seven.

In particular, said number of cuts is an odd number that is a multiple of a prime number, said prime number greater than or equal to five, said odd number selected from the group comprised of: fifteen, twenty-one, twenty-five, twenty-seven, thirty-three, thirty-five, thirty-nine, forty-five, forty-nine, fifty-one.

According to another aspect of the invention a laser device comprises a laser resonator as above defined.

Advantageously, said laser device comprises on at least one plane an ordered group of such laser resonators.

In a further exemplary embodiment, the perimeter of the resonator is linear, and the cuts which are formed by adjacent slits are at a predetermined distance from each other—This way, the efficiency of the vertical emission from the grating mode radiating vertically, its optical losses, as well as the amount of feedback can be controlled. Moreover, the output power in the vertical direction can be maximised, at the same time ensuring that only the symmetric mode can reach the laser threshold, producing regular, single-lobe beam profiles.

Advantageously, for THz QC lasers with a slit separation that is 0.6-0.7 times the grating period can be provided, to obtain the best lasing conditions.

According to a further aspect of the invention, a method is provided for making a planar resonator which is adapted to be associated to a laser, said method comprising the steps of:
prearranging a semiconductor active region;
prearranging a first and a second wave-guiding layer, said layers containing said active region, wherein said active region has a shape that is defined by a perimeter,

wherein said first wave-guiding layer is formed on said active region according to a lattice of cuts,

and wherein said cuts are made by at least two adjacent slits and a central zone in which metal is present.

Advantageously, the perimeter can be circular, and the cuts are radial cuts, said radial cuts can be made in such a way that the number of said cuts is a prime number or an odd number that is a multiple of a prime number, said prime number greater than or equal to five.

Alternatively, the resonator is linear, and the cuts which are formed by adjacent slits are at a predetermined distance from each other so as to maximize the output power in the vertical direction, and produce regular, single-lobe beam profiles. In particular, for THz QC lasers best results are generally achieved with a slit separation that is 0.6-0.7 times the grating period.

### BRIEF DESCRIPTION OF THE DRAWINGS

The invention will be made clearer with the following description of some exemplary embodiments, exemplifying but not limitative, with reference to the attached drawings wherein:

FIG. 1 shows a perspective view of a first embodiment of a laser resonator according to the present invention, which has a disc shape that comprises an outer layer that lies upon an active region that has peripheral radial cuts, where the number of the cuts is a prime number, where the radial cuts are shown also in an alternative version formed by two respective adjacent slits;

FIGS. 1A-1C show a cross-sectional view of further three possible embodiments of the laser resonator of FIG. 1;

FIG. 2 shows a perspective view of an exemplary embodiment, which has a ring shape that comprises an outer layer that lies on an active region that has radial cuts, where the number of the radial cuts is a prime number;

FIG. 3 shows a perspective view of a further exemplary embodiment, which has a ring shape that comprises an outer layer that lies on an active region that has radially oriented cuts, where the number of the radial cuts is a prime number;

FIGS. 4 and 5 respectively show a perspective view and a cross sectional view of fixing a conductive wire for exciting the resonator of FIG. 1 by means of an electric pulse;

FIG. 6 shows a cross sectional view of an embodiment of the laser resonator according to FIG. 5, where the active region is coated by a doped semiconductor layer;

FIG. 7 is a perspective view that shows the use of lead wire for exciting the resonator of FIG. 1C by means of an electric pulse, where the active region is coated by a doped semiconductor layer, which is missing in the central part;

FIG. 8 shows an exemplary embodiment of the cuts, as also shown in FIG. 1, that comprise at least two respective adjacent slits, such that the extension of the central zone of the cut without metal is reduced;

FIG. 9 shows the emission mode of a laser disc resonator which is similar to that of FIG. 1, but has an even number of cuts;

FIG. 10 shows the intensity of the preferred action laser mode of a laser resonator like that of FIG. 1, in which the number of cuts is a prime number;

FIGS. 11 and 12 show a laser emission diagram that is calculated by using a disc laser resonator like that of FIG. 9 and FIG. 10, respectively;

FIG. 13 compares two laser emission diagrams of a disc laser resonator that of FIG. 9 and with a laser disc laser resonator like that of FIG. 10, according to the invention, for a 3 Thz quantum-cascade type laser device, said laser devices having similar active regions;

FIG. 14 shows a laser device that comprises an ordered group of laser resonators according to FIG. 1, and arranged according to a plane.

FIG. 15, 15A show a perspective view of a prior art linear resonator and a detailed partial enlarged view;

FIG. 16, 16A show a perspective view of a dual slit linear resonator according to the invention and a detailed partial enlarged view with a ratio between slit separation and grating period and grating period about 0.6;

FIG. 17, 17A show a perspective view of another dual slit linear resonator according to the invention and a detailed partial enlarged view with a different ratio between slit separation and grating period, about 0.7;

FIG. 18, 18A show a perspective view of a further dual slit linear resonator according to the invention and a detailed partial enlarged view with a further different ratio between slit separation and grating period, about 0.5;

FIG. 19 shows the amount of radiation emitted from the laser top surface of the two grating modes symmetric (black dots) and antisymmetric (black squares) responsive to a change of the ratio between slit separation and grating period spanning between 0.5-0.7 and further. FIGS. 20 and 20A show a perspective view of a three slit linear resonator according to the invention, as an example of multiple slit linear resonator

### DETAILED DESCRIPTION OF SOME EXEMPLARY EMBODIMENTS

In the following description, as circular resonator a disc or ring plane resonator is intended, as well as an elliptical resonator, or a rectangular circularly or elliptically ending resonator is used, which can operate according to the mode “whispering gallery”.

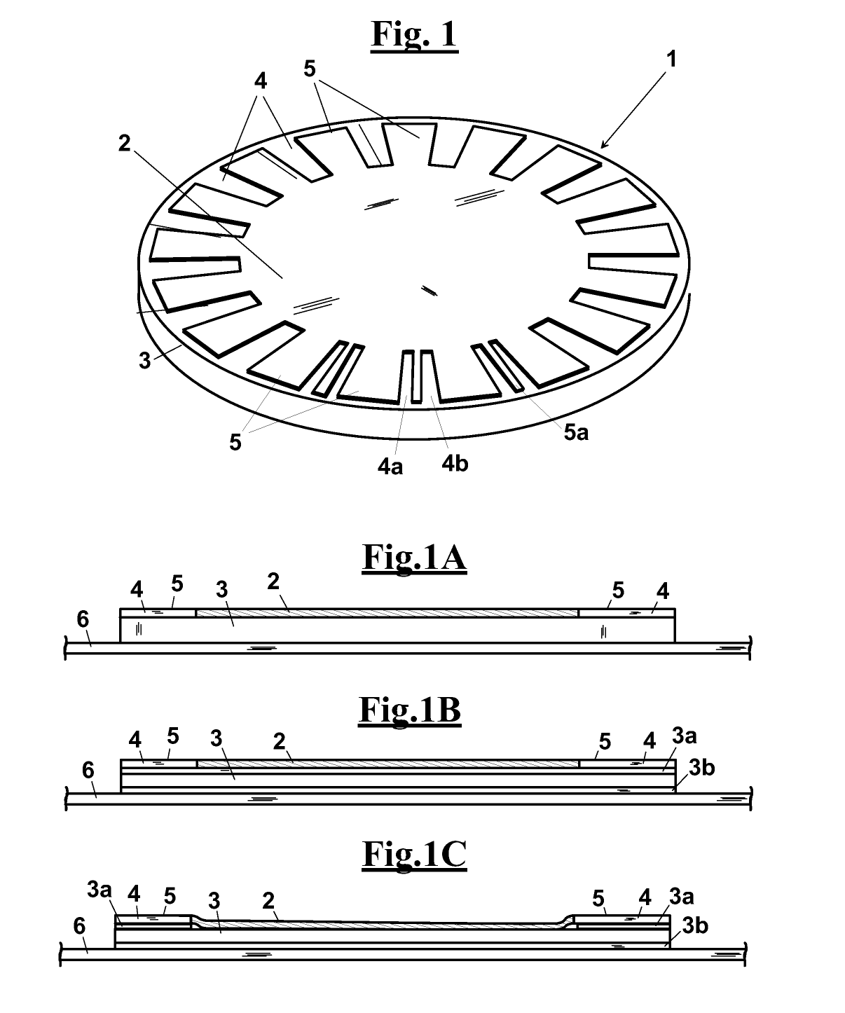

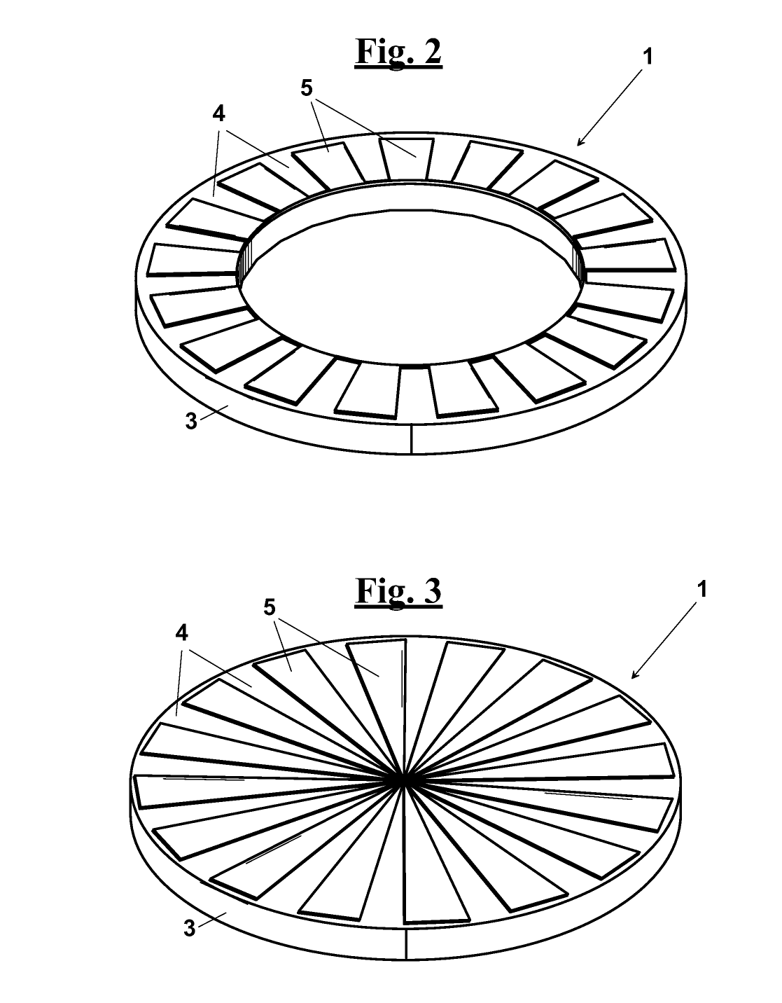

With reference to FIGS. 1 and 1A, in a first exemplary embodiment of the present invention, a disk shaped laser resonator 1 comprises an outer layer 2, mounted on an active region 3, at the boundary of which radial cuts 4 are made, through which inner active regions 3 are visible.

In FIG. 1 two possible versions of the cuts are shown, i.e. either an open cut 4, or a preferred version for THz QCLs, where two slits 4a and 4b are provided that are close to each other, separated by uncut portions 5a. In other embodiments, not shown in this figure, a plurality of slightly spaced apart slits are possible.

According to an aspect of the invention, the number of cuts 4 can be a prime number, for example five, seven, eleven, thirteen, seventeen, nineteen, twenty-three, twenty-nine, thirty-one, thirty-seven, forty-one, forty-three, forty-seven etc., or it is an odd number that is a multiple of a prime number, such prime number greater than or equal to five, for example fifteen, twenty-one, twenty-five, twenty-seven, thirty-three, thirty-five, thirty-nine, forty-five, forty-nine, fifty-one. In the specific case of FIG. 1, the number of cuts is seventeen, with the same number of portions 5 of outer layer 2 that define cuts 4, whose structure resembles the teeth of a gear. The squared shape of cuts 4, and of portions 5 that define them, is not limitative.

As shown in FIG. 1, no further layer is arranged above resonator 1, even if further plane layers can be applied, for example, planes made of a transparent material.

In particular, cuts 4 form a circumferential lattice which has a lattice filling factor, i.e. the ratio between the surface of cuts 4 and the surface of uncut zones 5, preferably set between 40% and 60%, or vice-versa. In the exemplary embodiment of FIG. 1, the ratio between full and empty zones along the perimeter is approximately 60/40%.

FIG. 1A shows a cross sectional view of active region 3 that rests on a layer 6, which forms together with layer 2 a radiation guide for electromagnetic signals that cross active region 3. Layers 2 and 6 can be made of a dielectric material or of a metal.

The disc or ring 1 overall thickness may be even only one micron, even if, as in case of double metal quantum-cascade laser devices, i.e. laser devices in which an active region 3 that is arranged between two metal layers 2 and 6, the overall thickness is set, for example, between five and fifteen microns.

In FIG. 1B an exemplary embodiment is shown where external sublayers 3a and 3b of active region 3 are formed by a doped semiconductor, to increase conductivity with respect to external layers 2 and 6, if they are made of metal.

In FIG. 1C a further exemplary embodiment is shown where outer central layer 3a of active region 3 is limited to the peripheral zone at cuts 4, and at portions 5 of layer 2 that define the cuts. In this case, the central portion is lowered, i.e. layer 2 in the central portion adheres directly to active region 3, whereas layer 3a is missing.

In FIG. 2, the central portion of layers 2 and 3 is missing, and the laser resonator has a ring shape.

In FIG. 3 an exemplary embodiment is shown where the length of cuts 4 is the same as the length of the disc radius, such that the latter start directly from the centre of the resonator, whereby the central cut-free zone is missing.

The pumping step of the laser resonator can be carried out by optical, electrical excitation, or by another excitation mode.

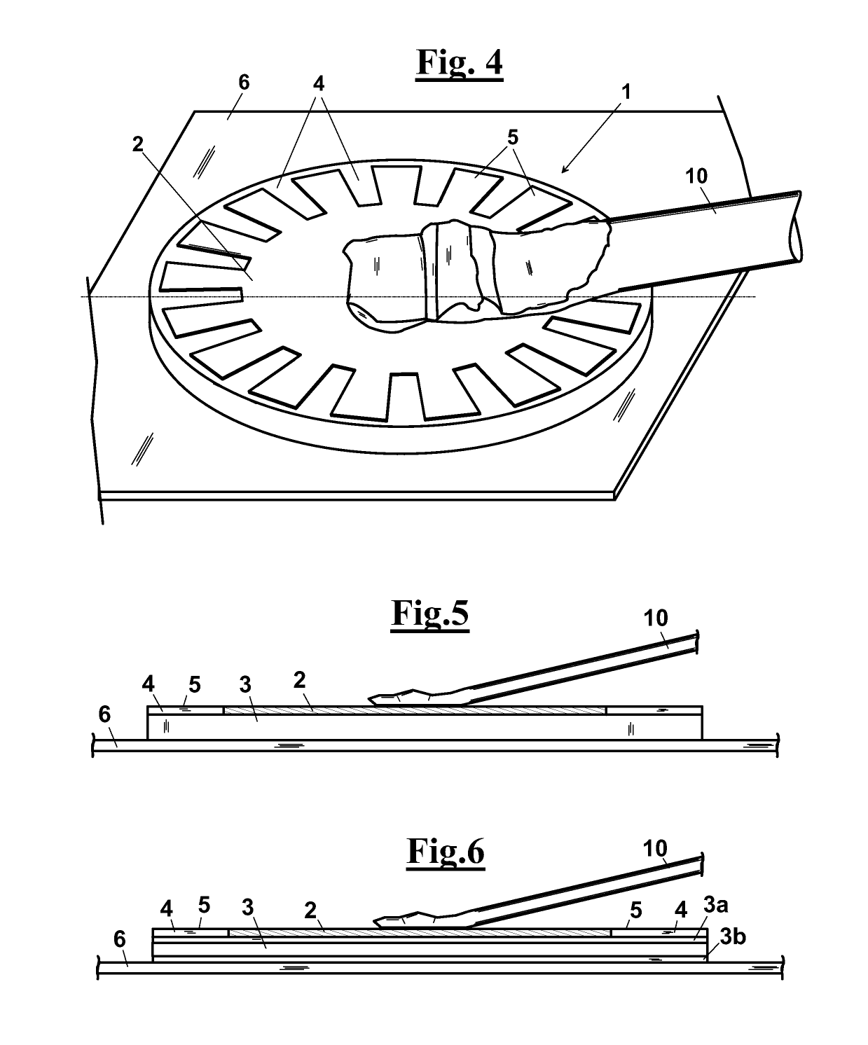

In FIGS. 4, 5 and 6 an electrical conductor 10 is shown, which may be a copper wire. The conductor has a diameter of one thousandth of an inch, and is fixed by hot bonding to the laser resonator of FIGS. 1, 1A and 1B, if it has metal-made layers 2 and 6. The pumping can be caused by various duration and duty cycle current pulses or by DC.

This is an advantageous solution for a disc laser resonator, while it is less useful for a ring laser resonator, like that of FIG. 2, owing to a lower electric pumping efficiency, since joining the electrical conductor in the central zone is somewhat troublesome.

The outer metal coating may be about 10-300 nm thick, and may be made of titanium/gold alloy, and may be joined to the wafer by a thermocompression procedure. The radial cuts may have various lengths, for example the length may range from 160 to 210 μm, and may be made of a thermally evaporated Cr/Au metallization that is laid by means of an optical lithography and a lift-off procedure. The cuts in the doped semiconductor layer are made by Induced Coupled Plasma Reactive Ion Etcher (ICP-RIE). In particular, the upper contact is engraved by using the metal as a self-aligned mask, whereas the central portions are engraved by a photoresist mask. Successively, the obtained devices are indium-welded on a copper base, and then they are joined with the lead wire and mounted on the cold finger of a liquid helium cryostat.

The diameter, the number of cuts and the length of the radial direction of the cuts, depends upon, or influence, the wavelength of the radiation that is emitted by the laser inside the semiconductor material. In possible embodiments, the disc has a diameter set between 170-180 micron, and the length of the cuts is about 20 micron. In this case, the wavelength of the emitted radiations is about 100 micron.

In alternative, instead, if the number of cuts is changed, for example, if it is lowered from seventeen to thirteen, or if it is increased to nineteen, and so on, the number of oscillation periods of the laser radiations respectively decreases or increases to thirteen or to twenty-three, and causes a variation of the wavelength of the laser radiations.

By choosing a prime number of cuts 4, the resonator is forced to “laser” only within the lattice that is formed by cuts 4 and by portions 5, provided the active material is excited. In the case of FIG. 1, as also shown in FIG. 10, seventeen oscillation periods of the electromagnetic field would exist, which propagate along the resonator plane, with a vertically directed resulting emission, i.e., an emission direction that is orthogonal to the resonator plane. This emission is extremely collimated and effective, and has a circular symmetry.

For better understanding this aspect, it is intuitively observed that, in a disc resonator, the permitted optical modes, which travel along the circumference, are characterized by the condition that the component of the wave vector of the radiations in the azimuth direction kₐ satisfies the relationship:

kₐ=2πn/L

where L is the length of the circumference of the disc and n an integer number. This condition simply derives from by the need that the electromagnetic wave, after travelling along the whole disc circumference, has exactly the same phase value as before.

The lattice, in order to effectively lead the radiations in a vertical direction, must work on the second order of diffraction, in other words the following relationship must be fulfilled:

kₐ=2π/Λ

where Λ is the pitch of the lattice, i.e. L=nΛ. In a true whispering gallery mode of a laser disc,

kₐ=2π/λ

where λ is the radiations wavelength in the semiconductor material, therefore the disc size and the lattice pitch should be selected such that

Λ=λ.

However, in a disc laser a component of the wave vector can exist also in a radial direction kᵣ; consequently, for a prefixed λ value, a laser can work according to a plurality of modes, in which:

kₐ≧2π/λ,

provided, in each case, that

2π/λ=√(kₐ²+kᵣ²).

Therefore, the laser might at any rate work according to a mode in which, for example:

kₐ=π/Λ

(first order lattice) that however would have:

L=2nΛ,

or still according to a mode in which

L=3nΛ

(where n is still an integer number), and so on, provided

kᵣ>0.

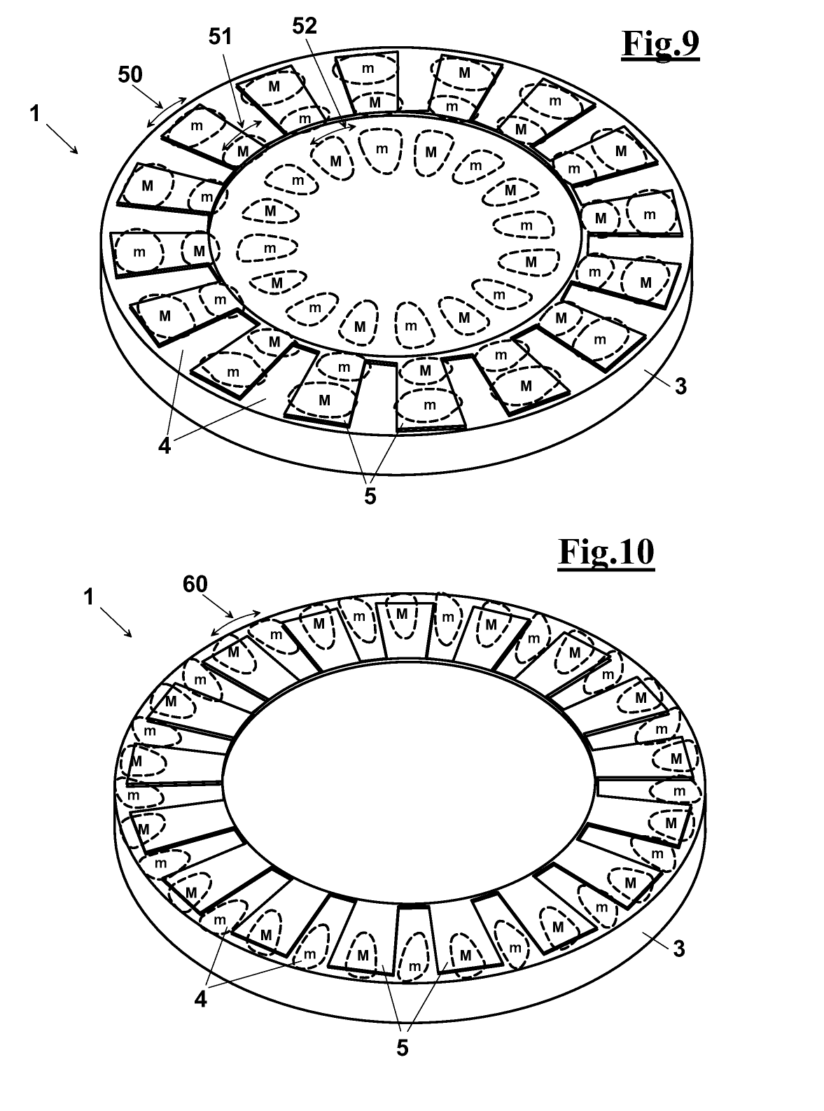

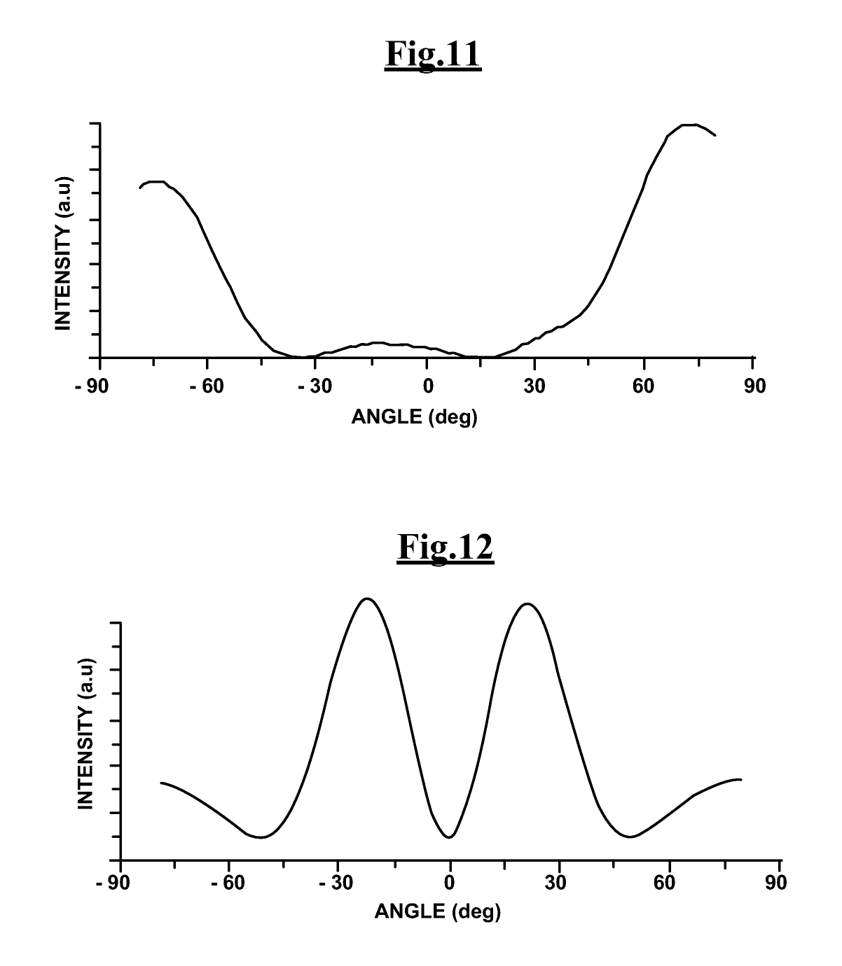

This is exemplified in FIG. 9, where a resonator is shown which has sixteen cuts, and in which the laser operates in the lattice according to a way that corresponds to a first order lattice, as shown by the azimuth distribution 50 of the maximum values M and the minimum value m, which are alternated for each cut, as characterized by kₐ=π/Λ. Maximum vales M and minimum values m extend also in a radial direction (L=2nΛL=3nΛ), with further azimuth distributions 51 and 52; as a consequence, a scarcely practical laser emission intensity is obtained (see hereinafter what is said about FIG. 11).

To assure that only the equation

kₐ=2π/Λ

is satisfied, the laser disc must be designed such that

L=mΛ,

where m is a prime number.
On the same subject, see FIG. 10, where a resonator is shown which has seventeen cuts, and in which the laser operates in the lattice according to a way that corresponds to a second order lattice, as shown by the azimuth distribution 60 of the maximum values M and the minimum value m, which are alternate for each cut that is characterized by kₐ=π/Λ.

Let still be λ the wavelength of the radiations emitted by the laser, Λ the lattice pitch, i.e., the distance between two cuts, and K=2π/λ the wave vector of the radiations: the lattice behaves as a second order lattice if the component of K in the circumferential or azimuth direction of the lattice is 2π/Λ (FIG. 10), whereas the lattice behaves as a first order lattice (FIG. 9) if the component of K in the circumferential direction of the lattice is π/Λ. This is possible, even if a same λ value is kept, which has a radial component that is different from zero. This radial component causes, however, a preferential emission direction that is no longer vertical.

Actually, if the number of cuts is a prime number, or if it is an odd number that is a multiple of prime numbers that are higher than five, along the boundary of the laser resonator, the lattice prevents the circumferential component from being π/Λ, therefore the lattice still behaves as a second order lattice and ensures a vertical emission.

This theoretical imposition is used for frequencies that are in the range of terahertz, even if the number of cuts is not a prime number, but it is an odd number that is a multiple of a prime number, said prime number greater than or equal to five. In this case, in fact, since the resonator is circular, even if it is theoretically possible that the resonator “lasers” on zones that are different from the lattice, i.e. towards the centre of the disc, at a distance that is a multiple of the wavelength, such areas would be impossible to be attained, due to the small diameter of the disc.

If the lattice coupling coefficient is set high enough (˜1/L or higher), the laser can work only according to a true whispering gallery mode, therefore the lattice is a true second order lattice and extracts most of the emitted radiations vertically.

The modes with kᵣ≠0 are modes that extend further towards the disc centre; in a device laser they might be preferred with respect to the true whispering gallery mode, which has less dispersion (due to the introduction of the lattice) and a higher electric pumping effectiveness (see the figure).

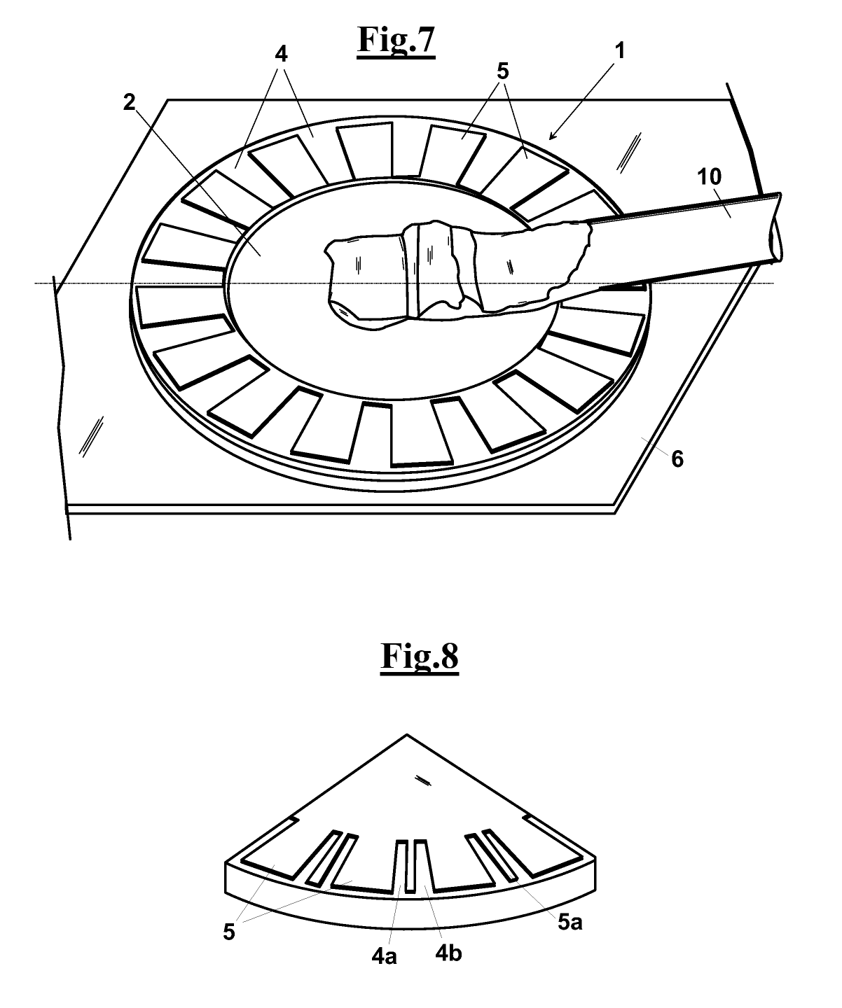

If the coupling coefficient is too low, such modes can be eliminated also by reducing the electric pumping in the central zone. This can be obtained with the exemplary embodiment of FIG. 7 which show electrical conductor 10 mounted on lowered central portion 2 of the resonator of FIG. 1C. In the central zone, the metal coating of upper layer 2 is slightly less by a few microns, due to the lack of doped layer 3a (to be seen in FIG. 1C). The laser resonator of FIG. 7 has the advantage of further forcing the resonator to “laser” in the peripheral lattice that is formed by cuts 4 and by zone 5, due to the lack of doped layer 3a in the central zone, and allows therefore a higher “pumping” in the peripheral zone where the lattice is present. This exemplary embodiment may be preferred in the case of “weak” lattice configurations, i.e., indeed, if the coupling coefficient is low.

Since the upper metallization acts also as an electric contact, it is possible to replace each cut 4 with two cuts that are close to each other, 4a and 4b, or with a plurality of slightly spaced apart cuts; this improves the electric pumping without affecting the vertical emission efficiency, and without changing the resonance mode. In fact, portions 5 remain unchanged, whereas the two (or more) cuts 4a and 4b are spaced apart by portions 5a, thus indeed improving the electric pumping without affecting the overall performances. This is particularly advantageous by laser devices that operate with higher wavelength, in which the width of a single cut would be too large to allow a uniform injection of electrons.

FIGS. 11 and 12 show a laser emission diagram that is calculated by using respectively a laser disc resonator as shown in FIGS. 9 and 10. As it can be observed (FIG. 11) the emitted intensity (shown in non-normalized arbitrary units) changes responsive to the angle formed by the radiation and the vertical direction, i.e. the direction normal to the plane of the laser resonator. In particular, the maximum of the emitted radiation is at angles higher than 60°, which compromises a practical use of the laser. As shown in FIG. 9, this is due to the fact that the propagation vector has a component different from zero also in the radial direction, and therefore a first order diffraction takes place in the lattice, or kₐ=kᵣ=π/Λ. On the contrary, as it can be seen in FIG. 12, the maximum of emission is obtained at angles that are about zero, i.e., about the vertical. Actually, the number of minimum or maximum values of the electric/magnetic field is half the number of cuts. As shown in FIG. 9, this is due to the fact that the propagation vector has a radial component that is different from zero along the lattice, and therefore a first order diffraction takes place within the lattice k_{azimuth}=π/Λ. In the latter case, the number of minimum or maximum values of the electric/magnetic field is equal to the number of cuts, and a second order diffraction takes place, k_{azimuth}=2π/λ.

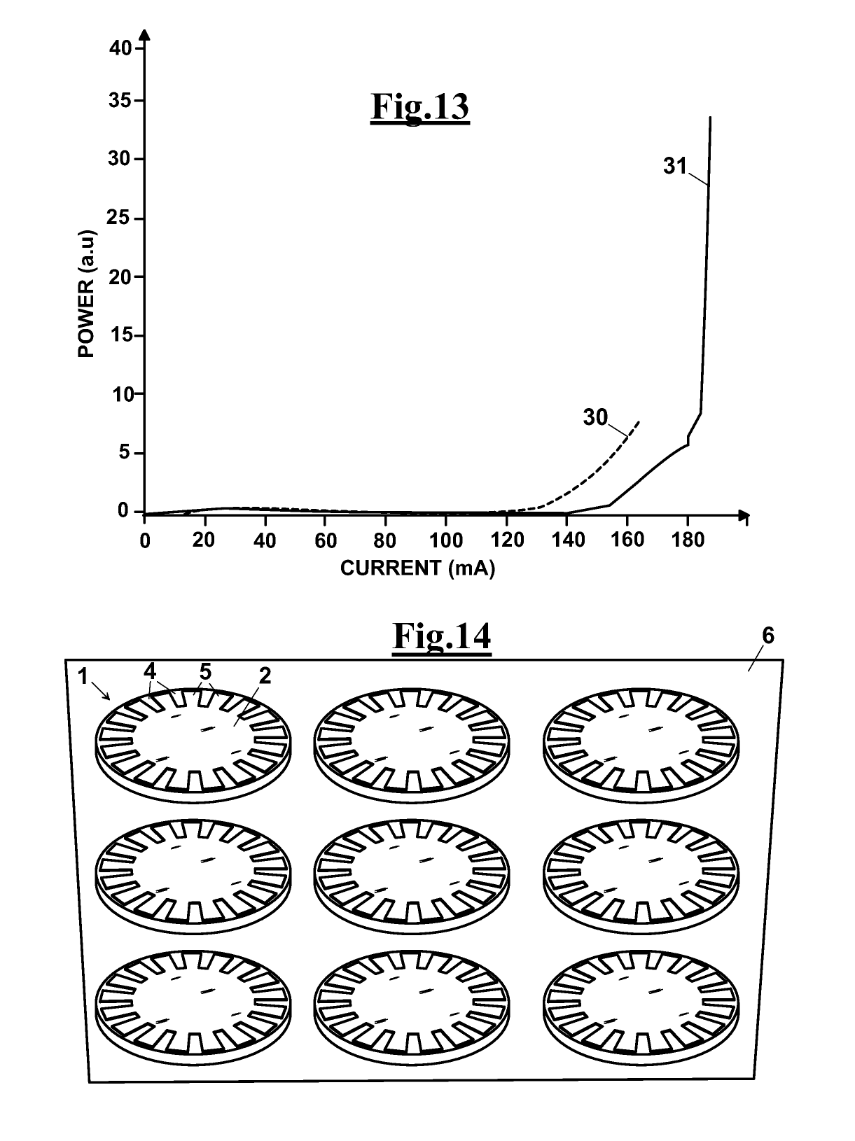

FIG. 13, shows a comparison of two laser emission diagrams which are respectively obtained by means of a laser disc resonator, as in the case of FIG. 9, and by means of a laser disc resonator, as in the case of FIG. 10. In particular, the difference is highlighted between:

the power that is achieved by the dotted curve 30, which refers to vertically emitted power responsive to the current intensity in the case of a resonator that has sixteen cuts and a 170 micron diameter,

the power that is achieved by continuous curve 31, which shows the relationship of emitted power versus current intensity in the case of a resonator with seventeen cuts and a 182 micron diameter. The diagram is limited to the limit at which the current can be tolerated. Evidence is given that the achieved power is extremely higher, and that the derivative of the power is even much higher, versus current intensity. This shows the large power that can be extracted with such a laser geometry, which forces the laser to emit only along the lattice.

With reference to FIG. 14, it is possible to provide a laser device that comprises an ordered group of laser resonators, as above described. For example, in the figure a plane is shown that forms metal layer 6, and has an ordered group of resonators 1 (FIG. 1) on top. Obviously, the structures of FIG. 1B or 1C can also be used, in a way that it is obvious to a skilled person.

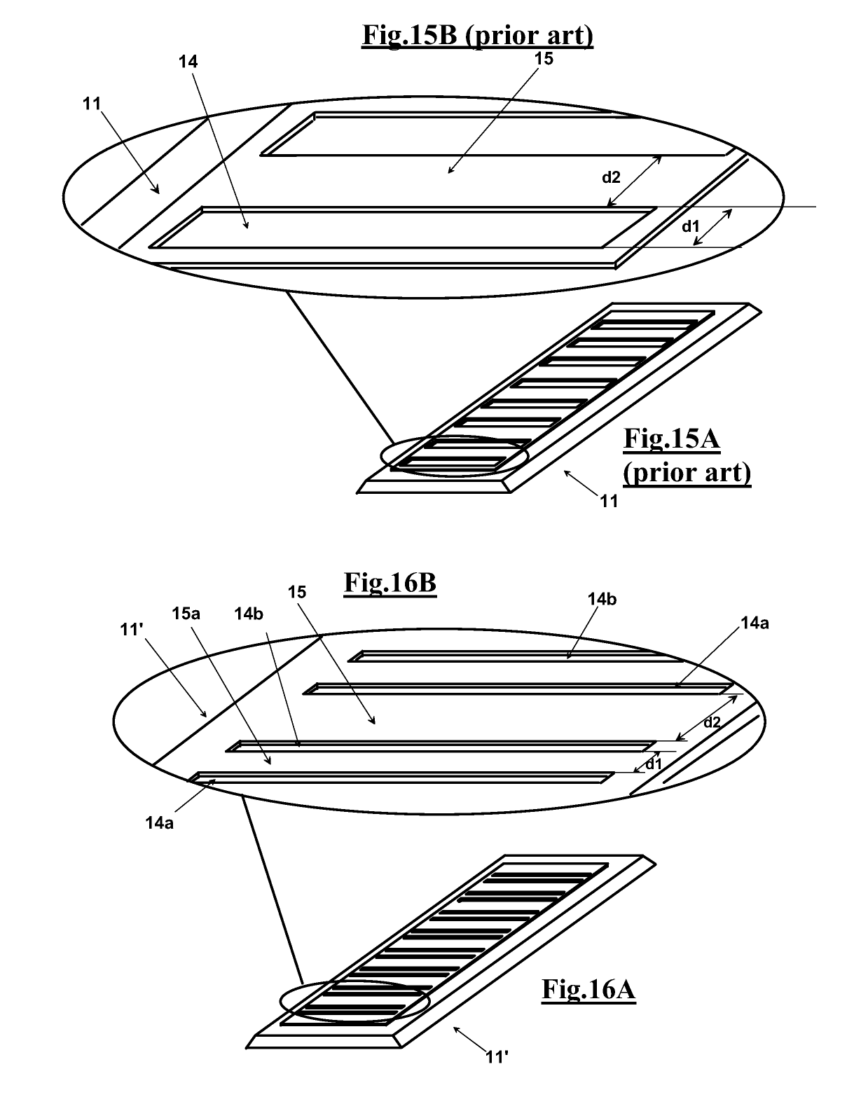

With reference to FIG. 15, in a known linear resonator 11, cuts 14 having a width D1 are arranged at a distance D2 from each other separated by uncut portions 15.

With reference to FIG. 16, according to one preferred aspect of the invention, a linear resonator 11′, similarly to the case of radial cuts disclosed above in FIGS. 1 and 8, the upper metallization can act also as an electric contact, and instead of each cut 14 of FIG. 15 two slits 14a and 14b are provided, which are close to each other substantially at a distance D1, separated by a metal coated part 15a. The distance between two couples of slits 14a and 14b is maintained the same as in FIG. 15, separated by uncut portions 15 having a width D2.

This feature improves the electric pumping without affecting the vertical emission efficiency, and without changing the resonance mode. In fact, the two cuts 14a and 14b are spaced apart by portions 15a, and the electric pumping is improved without affecting the overall performances. This is particularly advantageous by laser devices that operate with higher wavelength, such as THz QCLs, in which the width of a single cut (see cut 14 in FIG. 15) would be too large to allow a uniform injection of electrons.

The grating period is substantially D1+D2, since the width of the slits 14a and 14b is negligible (about 1/10 of the grating period). In FIG. 16 the ratio between slit separation and grating period is about 0.6. It should be noted that, for symmetry reasons, the ratio 0.6 calculated as about D1/D1+D2 is equivalent to a ratio 0.4 calculated as D2/D1+D2. The grating period is chosen according to the desired lasing wavelength, and is substantially equal to the wavelength.

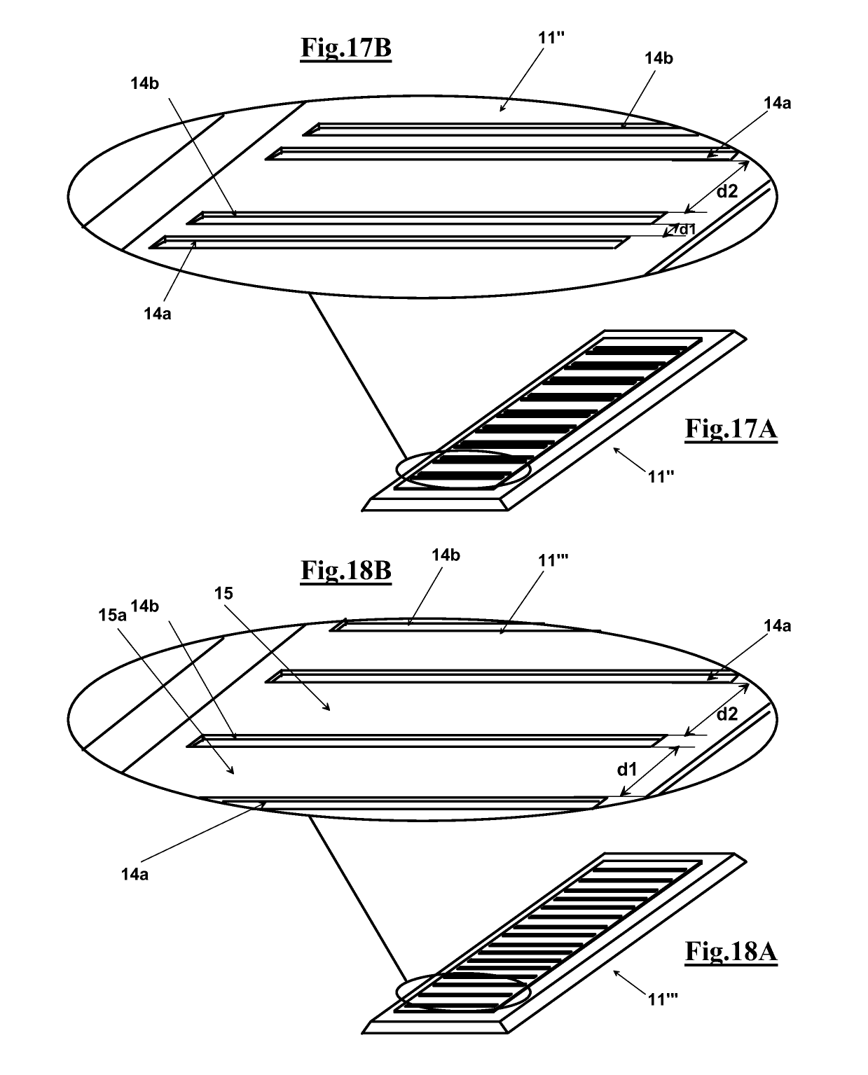

As shown in FIG. 16, 16A; as well as in FIGS. 17, 17A; 18, 18A for similar linear resonators 11″ and 11′″, whereas distance D1+D2, i.e. substantially the grating period, remains unchanged, the distance D1 between slits 14a and 14b may be changed (or equivalently the distance D2), and consequently changed the ratio between the widths of metal parts 15 and 15a. More precisely, the ratio between the distance between the slits and grating period (i.e. the lasing wavelength) can be 06 in FIG. 16; 07 in FIG. 17 and 0.5 in FIG. 18.

Distance D1 is chosen equal to a certain fraction of the grating period. Such distance D1 is chosen so as to provide the necessary amount of surface losses from the device to ensure that laser action can be achieved on a vertically emitting optical mode and with a maximum efficiency. The value of such distance depends on the characteristics of the laser waveguide and gain material.

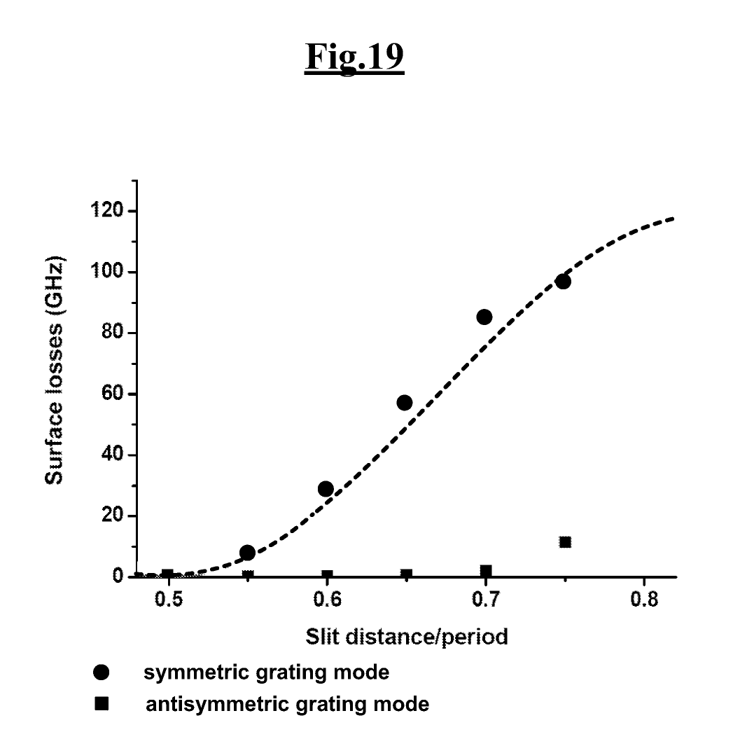

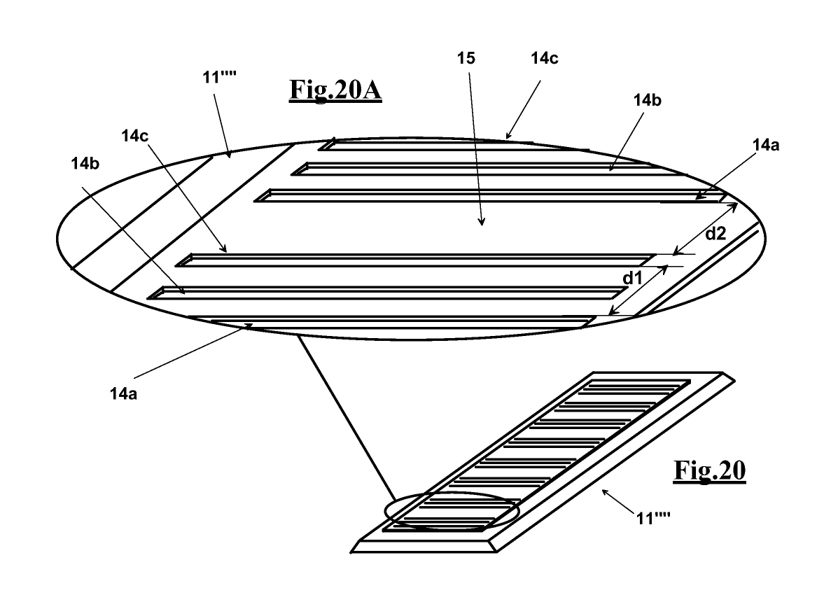

As shown in FIG. 19, for THz QCLs in metallic waveguides a preferable ratio between slit separation and grating period is 0.6-0.7 (i.e. approximatively FIGS. 16 and 17) whereas less interesting ration is 0.5, as in FIG. 18.

More precisely, FIG. 19 shows the amount of radiation emitted from the laser top surface of the dual-slit THz DFB laser resonators, like those of FIGS. 16, 17, 18 in the two grating modes, symmetric (black dots) and antisymmetric (black squares) responsive to a change of the distance between the slits 14a and 14b and consequently metal inner part 15a and metal outer part 15. In particular, by changing the distance between the slits 14a and 14b with respect to the grating period the losses of the symmetric mode can be tuned in a wide range without affecting those of the anti-symmetric one. This way one can tune the slit distance to achieve the best compromise between vertical power output, and laser threshold of the symmetric mode.

Alternatively, in a linear resonator 11″″, as shown in FIG. 20, 20a, three (or even more not shown) slightly spaced apart slits 14a 14b and 14c are provided. The efficiency of this configuration, as well as of other configuration with more than three slits, is similar to that of FIGS. 16 and 17, and is influenced by the ratio between the grating period and the cut width.

The foregoing description of a specific embodiment will so fully reveal the invention according to the conceptual point of view, so that others, by applying current knowledge, will be able to modify and/or adapt for various applications such an embodiment without further research and without parting from the invention, and it is therefore to be understood that such adaptations and modifications will have to be considered as equivalent to the specific embodiment. The means and the materials to realise the different functions described herein could have a different nature without, for this reason, departing from the field of the invention. It is to be understood that the phraseology or terminology employed herein is for the purpose of description and not of limitation.

What is claimed is:

1. A planar resonator which is adapted to be associated to a laser, said resonator comprising a planar active region, a first and a second wave-guide layer that define said active region; wherein said resonator has a shape that is defined by a perimeter, wherein a plurality of cuts of said first wave-guiding layer is provided along said perimeter, said cuts forming a lattice of cuts having a grating period, wherein said cuts are made by at least two adjacent slits and a zone between the slits in which an uncut portion of wave-guiding layer is present.

2. A resonator according to claim 1, wherein the perimeter is circular, and the cuts are radial cuts, and the number of said cuts is a prime number or an odd number that is a multiple of a prime number, said prime number greater than, or equal to, five.

3. A resonator according to claim 1, wherein said laser resonator is a Thz quantum-cascade laser, and comprises a semiconductor active region that is confined between two metal waveguides, in association to the lattice formed by said cuts that are located at the boundary of the disc.

4. A resonator according to claim 2, wherein said semiconductor active region is arranged between two doped semiconductor layers.

5. A resonator according to claim 3, wherein said first doped semiconductor layer is missing in a central zone.

6. A resonator according to claim 2, wherein said first and second wave-guide metal layers are made of a metal selected from the group consisting of: gold, chromium, palladium, titanium germanium, or combinations thereof selected among chromium/gold, palladium/germanium, and titanium/gold.

7. A resonator according to claim 2, wherein the lattice filling coefficient, i.e., the ratio between the surface of said cuts and the surface of uncut zones, is set between 40% and 60%, preferably is 50%.

8. A resonator according to claim 1, wherein said number of cuts is a prime number that is selected from the group consisting of: five, seven, eleven, thirteen, seventeen, nineteen, twenty-three, twenty-nine, thirty-one, thirty-seven, forty-one, forty-three, forty-seven.

9. A resonator according to claim 1, wherein said number of cuts is an odd number that is a multiple of a prime number, said prime number greater than or equal to five, said odd number selected from the group consisting of: fifteen, twenty-one, twenty-five, twenty-seven, thirty-three, thirty-five, thirty-nine, forty-five, forty-nine, fifty-one.

10. A resonator according to claim 1, wherein the perimeter is linear, and the cuts which are formed by adjacent slits are at a predetermined slit separation distance from each other equal to a chosen fraction of the grating period.

11. A resonator according to claim 11, wherein the ratio between slit separation and grating period is comprised between 0.5-0.8.

12. A resonator according to claim 11, wherein the ratio between slit separation and grating period is comprised between 0.6-0.7

13. A resonator according to claim 11, wherein said laser resonator is a THz quantum-cascade laser, and comprises a semiconductor active region that is confined between two metal layers, in association to a grating formed by cuts in the top metallic layer

14. A laser device comprising a resonator according to claim 1.

15. A laser device comprising a resonator according to claim 10, and comprising an ordered group of laser resonators, said ordered group arranged on at least one plane.
